(19) United States
(12) Patent Application Publication
(10) Pub. No.: US 2026/0204466 A1
(43) Pub. Date: Jul. 16, 2026

(54) AN ACTUATION STAGE, AN ELECTROMAGNET APPARATUS, AND METHOD OF FABRICATION

(71) Applicant: ASML Netherlands B.V., Veldhoven (NL)

(72) Inventors: Santiago E. DEL PUERTO, Myrtle Beach, SC (US); Justin Morrow BURCHFIEL, Norwalk, CT (US); Venkata Siva Chaithanya CHILLARA, Norwalk, CT (US); Bhushan Shrikant GAIKWAD, Stamford, CT (US)

(73) Assignee: ASML Netherlands B.V., Veldhoven (NL)

(21) Appl. No.: 19/134,976

(22) PCT Filed: Nov. 28, 2023
(86) PCT No.: PCT/EP2023/083409

§ 371 Date: Jun. 2, 2025

Related U.S. Application Data
(60) Provisional application No. 63/435,078, filed on Dec. 23, 2022.

(51) Int. Cl. H01F 7/20; G03F 7/00; H01F 41/02

(52) U.S. Cl. CPC H01F 7/20; G03F 7/70716; G03F 7/70758; H01F 41/02

(57) ABSTRACT

A stage (500) for supporting and moving an object (502) includes an electromagnet (510), first and second support structures (504; 506), a target (508), and a target-side bumper structure. The electromagnet can comprise a core, a wire coil (512), and a core-side bumper affixed to the core. The core, disposed on the first support structure (506), is made from magnetically permeable material. The core is shaped to have poles facing a same direction. The wire coil generates a magnetic field. The second support structure (504) supports and moves the object relative to the first support structure. The target (508) is disposed on the second support structure (504) to actuate the second support structure in response to the magnetic field. The target-side bumper structure is affixed to the target and can collide with the core-side bumper structure to establish a collision avoidance gap between the core and the target. An uncertainty value of the collision avoidance gap is less than 20 microns.

### CROSS-REFERENCE TO RELATED APPLICATION

This application claims priority of U.S. application 63/435,078 which was filed on 23 Dec. 2022 and which is incorporated herein in its entirety by reference.

### FIELD

The present disclosure relates to actuated stages, for example, a stage for supporting a reticle used in lithographic apparatuses and systems.

### BACKGROUND

A lithographic apparatus is a machine constructed to apply a desired pattern onto a substrate. A lithographic apparatus can be used, for example, in the manufacture of integrated circuits (ICs). A lithographic apparatus can, for example, project a pattern of a patterning device (e.g., a mask, a reticle) onto a layer of radiation-sensitive material (photoresist or simply “resist”) provided on a substrate.

To project a pattern on a substrate a lithographic apparatus can use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, can be used to form smaller features on a substrate than a lithographic apparatus which uses, for example, radiation with a wavelength of 193 nm.

A lithographic system can output only a finite number of fabricated devices in a given timeframe. Fast scanning of wafer stages and reticle stages can improve the speed of fabrication. However, efforts to produce the high forces for high acceleration of movable stages can be hindered by tolerance issues with the machining of parts. An electromagnet actuator can attract a target with a greater force and less electrical power consumption when the electromagnet is placed closer to the target. However, a gap should be maintained between the electromagnet and the target (to prevent collision therebetween) and the closer their distance, the more accuracy is demanded in machining tolerances.

### SUMMARY

Accordingly, it is desirable to improve lithographic fabrication speed and throughput. Electromagnetic actuators for wafer and reticle stages can be fabricated with tight tolerances according to aspects described herein.

In some aspects, a stage for supporting and moving an object can comprise an electromagnet, first and second support structures, a target, and a target-side bumper structure. The electromagnet can comprise a core, a wire coil, and a core-side bumper structure. The core can be disposed on the first support structure. The core can comprise magnetically permeable material. The core can be shaped such that poles of the core are disposed facing a same direction. The wire coil can be configured to generate a magnetic field in the core. The core-side bumper structure can be affixed to the core. The second support structure can be configured to support the object and move the object relative to the first support structure. The target can be disposed on the second support structure. The target can be configured to actuate the second support structure in response to the generating of the magnetic field. The target-side bumper structure can be affixed to the target. The target-side bumper structure can be configured to collide with the core-side bumper structure to establish a collision avoidance gap between the core and the target. The uncertainty value of the collision avoidance gap can be less than approximately 20 microns.

In some aspects, an electromagnet apparatus can comprise a core and a detachable wire coil assembly. The core can comprise magnetically permeable material. The core can be shaped such that poles of the core are disposed facing a same direction. The detachable wire coil assembly can comprise a wire coil and a housing. The wire coil can be configured to generate a magnetic field in the core. The housing can comprise a conduit configured to guide cooling fluid to regulate a temperature of the wire coil.

In some aspects, a method of fabricating an electromagnetic actuator can comprise one or more of the following operations. The method can include affixing a core of an electromagnet to a core support structure. The core can comprise magnetically permeable material. The core can be shaped such that poles of the core are disposed facing a same direction. The core support structure can comprise a core-side bumper structure affixed to the core. The method can include affixing a target-side bumper structure to a target. The target can have a pole-facing side that faces the poles. The target can be movable in response to a magnetic field generated via the core. The target-side bumper structure can be configured to collide with the core-side bumper structure to establish a collision avoidance gap between the core and the target. The method can include adjusting the collision avoidance gap to within a tolerance of approximately 20 microns or less. The adjusting can comprise surface-treating core-side structures. The surface-treating of core-side structures can include surface-treating the poles. The surface-treating of core-side structures can also include surface-treating the poles. The adjusting can comprise surface-treating target-side structures. The surface-treating of target-side structures can include surface-treating the pole-facing side. The surface-treating of target-side structures can also include surface-treating a collision region of the target-side bumper structure while affixed to the target.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 1C shows a lithographic cell, according to some aspects.

FIGS. 2 and 3 show a reticle stage, according to some aspects.

FIG. 4 shows a reticle exchange apparatus, according to some aspects.

FIGS. 5, 6, and 7 show actuated stages, according to some aspects.

FIGS. 8 and 9 show a flowcharts of methods, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

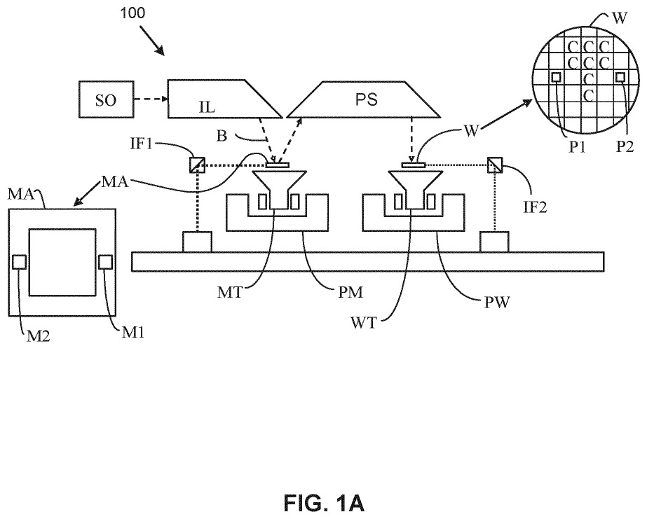

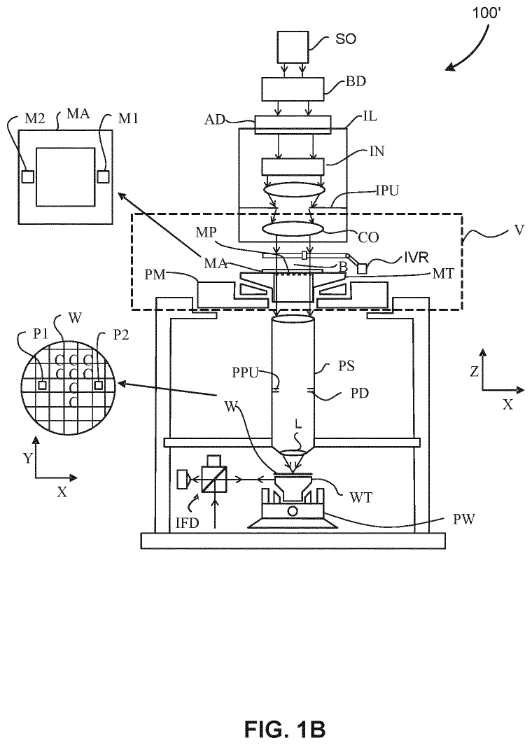

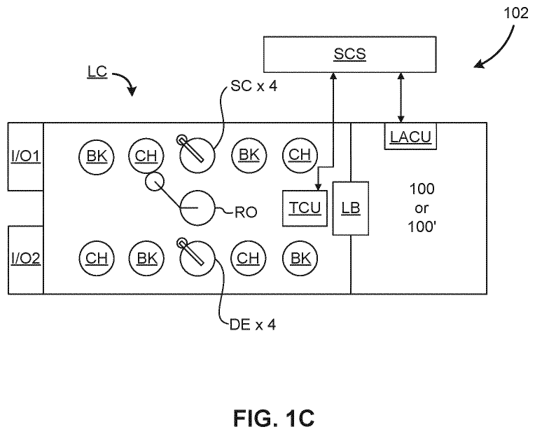

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some aspects, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

In some aspects, lithographic apparatus 100′ includes a deep ultraviolet (DUV) source, which is configured to generate a beam of DUV radiation for DUV lithography. In general, the DUV source is configured in a radiation system, and a corresponding illumination system is configured to condition the DUV radiation beam of the DUV source.

### Example Lithographic Cell

FIG. 1C shows a lithographic cell 102, also sometimes referred to a lithocell or cluster, according to some aspects. Lithographic apparatuses 100 or 100′ can form part of lithographic cell 100. Lithographic cell 102 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Reticle Stage

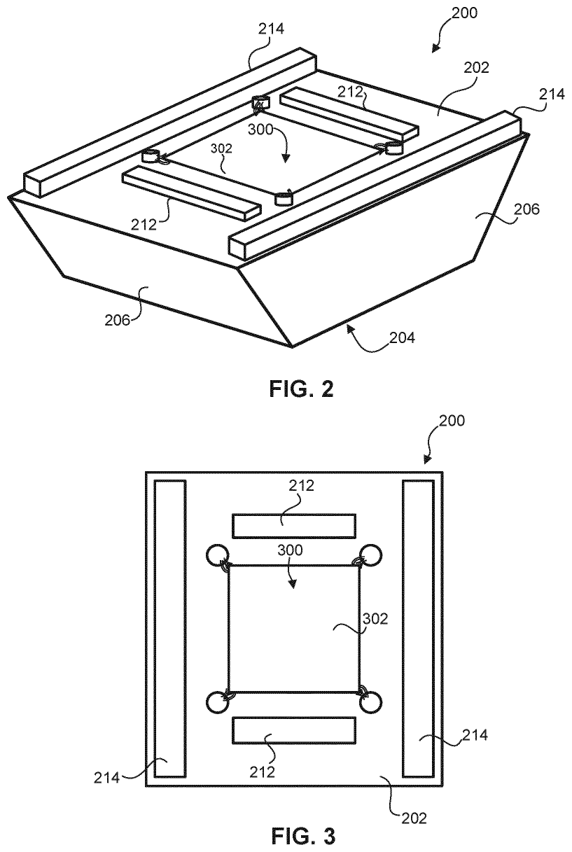

FIGS. 2 and 3 show a reticle stage 200, according to some aspects. Reticle stage 200 can include top stage surface 202, bottom stage surface 204, side stage surfaces 206, and clamp 300. In some aspects, reticle stage 200 with clamp 300 can be implemented in lithographic apparatus LA. For example, reticle stage 200 can be support structure MT in lithographic apparatus LA. In some aspects, clamp 300 can be disposed on top stage surface 202. For example, as shown in FIG. 2, clamp 300 can be disposed at a center of top stage surface 202 with clamp frontside 302 facing perpendicularly away from top stage surface 202.

In some lithographic apparatuses, for example, lithographic apparatus LA, a reticle stage 200 with a clamp 300 can be used to hold and position a reticle 408 for scanning or patterning operations. In one example, the reticle stage 200 can rely on powerful drives, large balance masses, and heavy frames to support it. In one example, the reticle stage 200 can have a large inertia and can weigh over 500 kg to propel and position a reticle 408 weighing about 0.5 kg. To accomplish reciprocating motions of the reticle 408, which are typically found in lithographic scanning or patterning operations, accelerating and decelerating forces can be provided by linear motors that drive the reticle stage 200.

In some aspects, as shown in FIGS. 2 and 3, reticle stage 200 can include first encoder 212 and second encoder 214 for positioning operations. For example, first and second encoders 212 and 214 can be interferometers. First encoder 212 can be attached along a first direction, for example, a transverse direction (i.e., X-direction) of reticle stage 200. And second encoder 214 can be attached along a second direction, for example, a longitudinal direction (i.e., Y-direction) of reticle stage 200. In some aspects, as shown in FIGS. 2 and 3, first encoder 212 can be orthogonal to second encoder 214.

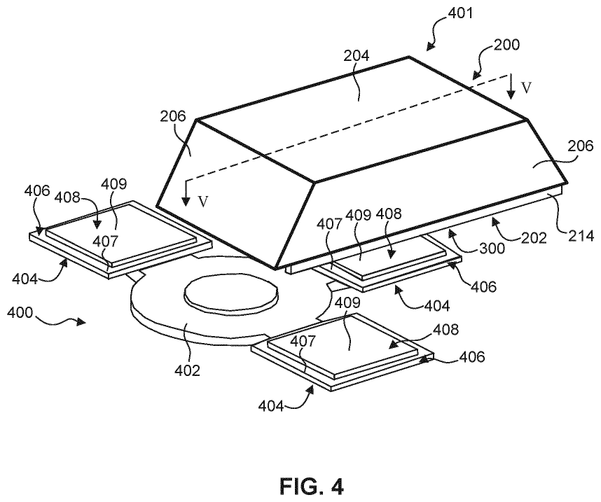

As shown in FIGS. 2 and 3, reticle stage 200 can include clamp 300. Clamp 300 is configured to hold reticle 408 in a fixed plane on reticle stage 200. Clamp 300 includes clamp frontside 302 and can be disposed on top stage surface 202. In some aspects, clamp 300 can use mechanical, vacuum, electrostatic, or other suitable clamping techniques to hold and secure an object. In some aspects, clamp 300 can be an electrostatic clamp, which can be configured to electrostatically clamp (i.e., hold) an object, for example, reticle 408 (FIG. 4) in a vacuum environment. For EUV generation performed in a vacuum environment, it can be difficult to use vacuum clamps to clamp a mask or reticle. Instead, electrostatic clamp(s) can be used. For example, clamp 300 can include an electrode, a resistive layer on the electrode, a dielectric layer on the resistive layer, and burls projecting from the dielectric layer. In use, a voltage can be applied to clamp 300, for example, several kV. And current can flow through the resistive layer, such that the voltage at an upper surface of the resistive layer will substantially be the same as the voltage of the electrode and generate an electric field. Also, a Coulomb force, attractive force between electrically opposite charged particles, will attract an object to clamp 300 and hold the object in place. In some aspects, clamp 300 can be a rigid material, for example, a metal, a dielectric, a ceramic, or a combination thereof.

### Example Reticle Exchange Apparatus

FIG. 4 shows a reticle exchange apparatus 401, according to some aspects. Reticle exchange apparatus 401 can be configured to minimize reticle exchange time, particle generation, and contact forces or stresses from clamp 300 and/or reticle 408 to reduce damage to clamp 300 and reticle 408 and increase overall throughput in a reticle exchange process, for example, in a lithographic apparatus LA.

Reticle exchange apparatus 401 can include reticle stage 200, clamp 300, and in-vacuum robot 400. In-vacuum robot 400 can include reticle handler 402.

In some aspects, reticle handler 402 can be a rapid exchange device (RED), which is configured to efficiently rotate and minimize reticle exchange time. For example, reticle handler 402 can save time by moving multiple reticles from one position to another substantially simultaneously, instead of serially.

In some aspects, reticle handler 402 can include one or more reticle handler arms 404. Reticle handler arm 404 can include reticle baseplate 406. Reticle baseplate 406 can be configured to hold an object, for example, reticle 408.

In some aspects, reticle baseplate 406 can be an extreme ultraviolet inner pod (EIP) for a reticle. In some aspect, reticle baseplate 406 includes reticle baseplate frontside 407, and reticle 408 includes reticle backside 409.

In some aspects, reticle baseplate 406 can hold reticle 408 such that reticle baseplate frontside 407 and reticle backside 409 each face top stage surface 202 and clamp frontside 302. For example, reticle baseplate frontside 407 and reticle backside 409 can be facing perpendicularly away from top stage surface 202 and clamp frontside 302.

In some aspects, as shown in FIG. 4, reticle handler arms 404 can be arranged symmetrically about reticle handler 402. For example, reticle handler arms 404 can be spaced from each other by about 90 degrees, 120 degrees, or 180 degrees. In some aspects, reticle handler arms 404 can be arranged asymmetrically about reticle handler 402. For example, two reticle handler arms 404 can be spaced from each other by about 135 degrees, while another two reticle handler arms 404 can be spaced from each other by about 90 degrees.

In some aspects, during a reticle exchange process, reticle stage 200 with clamp 300 can be adjusted in a multi-stage movement (e.g., long stroke stage (coarse motion), short stroke stage (fine motion)).

### Example Actuated Stage

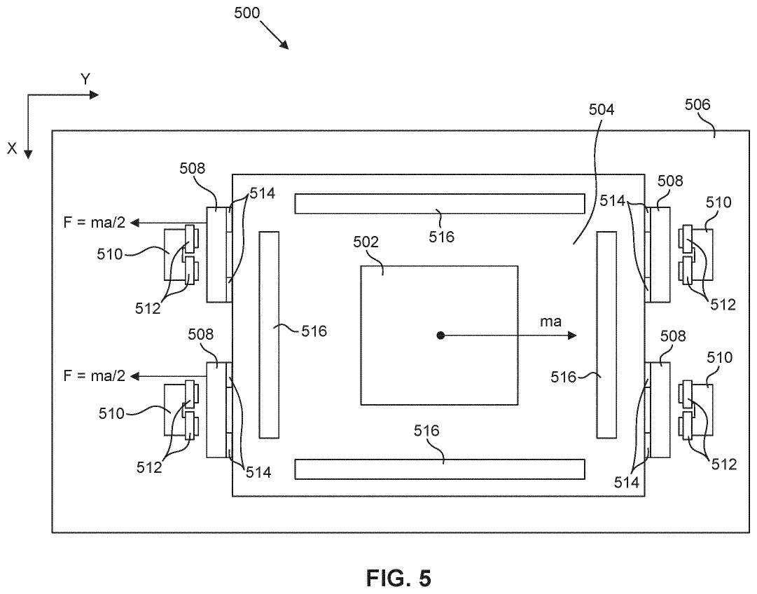

FIG. 5 shows a stage 500 for supporting an object 502, according to some aspects. In some aspects, stage 500 can represent a different view of reticle stage 200 to emphasize additional details. Stage 500 can comprise a support structure 504 (e.g., a second support structure), a support structure 506 (e.g., a first support structure), actuator devices 510, and actuator targets 508. Actuator devices 510 can comprise coils 512 (e.g., wires that are coiled around a ferromagnetic core). Actuator target 508 can be disposed and affixed on support structure 504 using affixing structures 514 (e.g., epoxy). The number and configuration of actuator-related elements are not limited to those shown in FIG. 5. Fewer or more actuator-related elements can be used, as well as other configurations. Stage 500 can also comprise one or more positional indicators 516 (e.g., encoder scales).

In some aspects, enumerative adjectives (e.g., “first,” “second,” “third,” or the like) can be used to distinguishing like elements without establishing an order, hierarchy, quantity, or permanent numeric assignment. For example, the terms “first support structure” and “second support structure” can be used in a manner analogous to “i^{th} support structure” and “j^{th} support structure” so as to facilitate the distinguishing of two support structures without specifying a particular order, hierarchy, quantity, or immutable numeric correspondence, unless otherwise noted.

In some aspects, stage 500 can be used in lithographic apparatus LA (FIG. 1), a lithographic cell (e.g., an arrangement of a multiple lithographic apparatuses), inspection apparatuses, or any apparatus in general that has a stage implementation for supporting and moving an object. For example, stage 500 can show a specific implementation of wafer table WT or mask table MT (FIG. 1).

In some aspects, support structure 506 can be an actuated structure (e.g., for coarse motion of object 502). In a lithographic fabrication process, object 502 can be a reticle, a wafer, or the like. Furthermore, stage 500 can also include additional movement budget to shuttle object 502 to and from a loading area. Therefore, support structure 506 can be responsible for a coarse motion of stage 500, e.g., in the order of tens, hundreds, or thousands of millimeters. Other distances may be chosen based on suitability for a particular implementation. However, in implementations where coarse motion is not needed, support structure 506 can be a static frame.

In some aspects, support structure 504 can be supported by support structure 506 while also allowing relative movement between the two support structures. The motion of support structure 504 can be limited to an axis (e.g., Y-axis) using guide rails or a contactless method (e.g., magnetic levitation) (guide devices not shown). The coordinate axes X and Y are provided as an example and are not to be construed as limiting. Actuator devices 510 can be responsible for fine adjustments of a position of support structure 504. Therefore, some aspects use a small gap between actuator devices 510 and their corresponding actuator targets 508. For example, a gap can be a few millimeters or less (e.g., less than approximately 1 mm). In a scanning lithographic process, printed devices can have critical dimensions in the sub-micron or sub-nanometer range. A movement budget of a millimeter can be large enough for scan-printing of sub-nanometer devices.

In some aspects, actuator devices 510 can be disposed and affixed on support structure 506. Actuator devices 510 can actuate support structure 504 by interacting with actuator targets 508. Actuator targets 508 can comprise a material that responds to magnetic fields (e.g., a metal, iron, ferrite, or the like). Actuator devices 510 can be electromagnets. The electromagnets can generate and adjust magnetic fields. An electromagnet can comprise coils 512 of wire wrapped around a metal core (e.g., a ferrite core). Actuator devices 510 can operate as attract-only if actuator targets 508 are not permanent magnets. Conversely, actuator devices 510 can repel and attract a permanent-magnet version of actuator target 508 by reversing a direction of the magnetic field. The actuator setup described herein can be referred to by other terms of art (e.g., a reluctance actuator; and it follows that actuator target 508 can be referred to as a reluctance target).

In some aspects, actuator devices 510 can actuate support structure 504 using a high acceleration. The acceleration can be, for example, approximately 4-100 g, 10-50 g, 20-40 g, or the like (where g is 9.8 m/s²). A high acceleration can increase lithographic print production (e.g., increase throughput). Lithographic pattern transfer can be performed when support structure 504 is in motion, for example, when it reaches a constant coasting speed. Coasting speeds can be, for example, 0.5-10.0 m/s, 1.0-7.0 m/s, 3.0-5.0 m/s, or the like. Performing the pattern transfer at a constant scanning speed can result in more accurate transfers of the printed pattern, whereas printing during acceleration can be accompanied by larger positional uncertainties.

The term “throughput” can be understood as the amount of material or items passing through a system or process. In some aspects, the term “throughput” can be used to characterize a rate of lithographic fabrication. For example, throughput can refer to a rate at which lithographic fabrication is completed on wafers, a rate at which a wafer clears a particular fabrication step and moves to the next step, or the like. Throughput can be a performance marker of a lithographic apparatus. It is desirable for lithographic systems to output as many products as possible in as little time as possible. Lithographic fabrication can comprise several complex processes. Each part of the process can involve tradeoffs that balance quality (e.g., sub-nanometer accuracy, high yield) and drawbacks (e.g., slower fabrication, cost). For example, to improve pattern-transfer speeds, lithography can implement faster, yet accurate, actuation of substrates and/or masks.

In some aspects, the nature of magnetic fields can be that a repulsive interaction is unstable and can create undesirable side forces (orthogonal to the direction of repulsion) and undesirable orthogonal torques. The orthogonal forces/torques tend to move the magnets in such a way as to change the interaction from repulsive to attractive, in order to minimize the total potential energy of the magnet set. Without external lateral guidance or constraining forces the arrangement is unstable and jumps to the closest stable equilibrium position, with gaps closing (no longer levitating). Consequently, repulsion systems using permanent magnets can be challenging to engineer and can prompt the addition of active controls to keep the arrangement from collapsing, or external mechanical guides. The additional complexity of lithographic systems can significantly increase engineering difficulty. Therefore, in some aspects, actuator devices 510 can be designed to operate using attraction only (or pull-only). With actuator devices 510 at opposite sides of support structure 504, it is possible to impart both forward and backward motion to support structure 504 while using a pull-only configuration. However, a pull-only method can have certain drawbacks, as will be discussed further below.

In some aspects, object 502 can be temporarily affixed onto support structure 504 by pressing object 502 onto support structure 504. This can be accomplished by vacuum clamping (suction force), electrostatic clamping (electrostatic force), mechanical clamping, or the like. Under ideal conditions, mutual friction between object 502 (e.g., a reticle) and support structure 504 (e.g., a chuck) can ensure that there is no slippage therebetween. However, mechanical stresses due to high accelerations can induce some slippage, resulting in printing error. The errors can be highly detrimental due to the possibility of losing thousands of device products by the time the error can be detected.

The following is an example of a positioning error of object 502 when using stage 500. In some aspects, object 502 can be affixed onto support structure 504. In order to determine a position of features on object 502, a calibration measurement can be performed using, for example, an optical inspection system. The calibration measurement can determine the position of features on object 502 relative to one or more positional indicators 516. Positional indicators 516 can be rigidly affixed to support structure 504. With the relationship between object 502 and one or more positional indicators 516 established, object 502 can be used for high precision processes (e.g., lithographic processes) and the calibration need not be carried out again so long as object 502 remains stationary with respect to support structure 504.

In some aspects, an electromagnetic force can be applied by actuator devices 510 on actuator targets 508. For example, actuator devices 510 on the left side of support structure 504 can be activated, which then pull on the corresponding actuators 508, affixing structures 514, and finally support structure 504. It follows that actuator devices 510 on the right side of support structure 504 can be used to pull in the opposite direction (for deceleration) and allow support structure 504 to come to rest. During acceleration/deceleration, the combined mass of object 502 and support structure 504 are inertial, and they exert a force that is equal and opposite to the force exerted by actuator targets 508 during the pulling (drawn as the arrow “ma” (mass×acceleration) pointed to the right). Conversely, if two actuator targets 508 are doing the pulling, then the pulling force can be split between the two actuator targets 508 (drawn as two arrows “F=ma/2”).

In some aspects, an actuator target 508 and a corresponding actuator device 510 can be separated by a gap. The gap can determine quality and performance of the actuation. For example, if a gap is too large, the attractive magnetic force may be too weak to impart enough acceleration on support structure 504 to meet throughput goals. If the gap is too small, then there is a risk of collision between actuator targets 508 and actuator devices 510. It is desirable to engineer structural tolerances of these elements down to tens of microns in order to achieve a strict tolerance for the gap.

Some aspects described herein provide structures and functions to address issues related to tolerances in manufacturing actuator devices and targets.

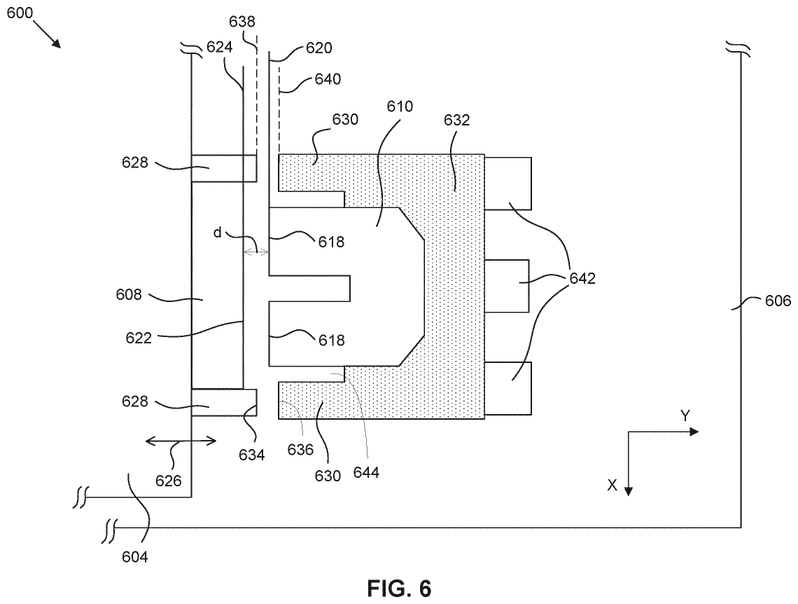

FIG. 6 shows a portion of a stage 600, according to some aspects. In some aspects, stage 600 can comprise a different view of stage 500 (FIG. 5) for illustrating additional details. For clarity purposes, new elements may be shown while some may be hidden or unlabeled (e.g., coils are not shown, but are understood to be present). Therefore, unless otherwise noted, descriptions of elements of FIG. 5 can also apply to FIG. 6. Elements appearing in FIG. 6 that correspond to elements in FIG. 5 can have like reference numbers (e.g., reference numbers sharing the two right-most numeric digits). Examples of such elements in FIG. 6 can include, for example, support structures 604 and 606, actuator target 608, and core 610 (e.g., an actuator device).

In some aspects, core 610 can comprise poles 618. As a non-limiting example, core 610 be shaped to have poles 618 facing a same direction (e.g., C-shaped core). Magnetic flux can be perpendicular to a surface of poles 618. A surface area of poles 618 (e.g., combined area of both poles) can determine a magnitude of magnetic interaction (e.g., a magnitude of magnetic force). The surface of poles 618 can define a plane 620. Actuator target 608 can comprise a pole-facing side 622. Pole-facing side 622 can define a plane 624.

In some aspects, bumper structures can be implemented in order to prevent collisions of fast moving objects (e.g., in the event of power loss in a lithographic apparatus). It can be undesirable to allow actuation target 608 to collide with core 610. Collisions can cause structures to become damaged and/or contaminate the clean lithographic environment by releasing contamination particles that can land on reticles and/or wafers. Therefore, actuator target 608 and core 610 can be protected by target-side bumper structures 628 and core-side bumper structures 630. One or more of each bumper type can be implemented. The bumpers can be arranged to maintain a non-zero gap distance d (defined in FIG. 6 as the distance between plane 624 of pole-facing side 622 and plane 620 of poles 618). Target-side bumpers 628 can be affixed to actuation target 608. Core-side bumpers 630 can be affixed to core 610.

In some aspects, core-side bumpers 630 can be affixed to a core support structure 632. Core-side bumpers 630 can be a monolithic appendage of core support structure 632 (e.g., of the same block of material). Core support structure 632 can be affixed to core 610, thereby securing a relative position between the surface of poles 618 and core-side bumpers 630.

In some aspects, support structure 604 (e.g., second support structure) can be configured to move relative to support structure 606 along direction 626 (e.g., parallel to X axis). Support structure 604 can support an object 502 (FIG. 5). Support structure 604 be used for fine positional adjustments of object 502 (FIG. 5). In the context of lithographic pattern transfer, a position of object 502 can be finely adjusted, thereby allowing accurate lithographic printing down to sub-nanometers. The magnetic force for moving support structure 604 (the force exerted on actuator target 608) can depend on how close the electromagnet is to the target (i.e., smaller distance d corresponds to a greater force). At larger distance d, the force will be reduced unless a current through coils 512 (FIG. 5) is increased. The force exerted by an electromagnet can be quantified according to the following equations:

$$F = \frac{{B}^{2} A}{2 {μ}_{0}} ; \qquad ( Eq . 1 )$$

$$B ∼ \frac{{μ}_{0} NI}{d} . \qquad ( Eq . 2 )$$

In some aspects, the force F is the force that an electromagnet using core 610 can exert on actuator target 608. The field B is a magnitude of the magnetic field in core 610. The area A can be a combined surface area of poles 618. The permeability μ₀ is the magnetic permeability of free space. Turns N is the number of turns of coils 512 (FIG. 5) around core 610. The current I is the current through coils 512 (FIG. 5). And the distance d is as shown in FIG. 6. The approximation of equation 2 is facilitated by considering the magnetic permeability of core 610 to be much greater than the permeability of air or free space. While an ideal material for core 610 would be capable of supporting an infinite amount of B-field, in practice, magnetically permeable materials can have a saturation limit. In other words, at the saturation limit, increasing the current I can result in severe diminishing returns to the increase of the B-field. And, therefore, the consumed power P can continue to increase with little to no increase to the force F (P=I²R; where R is the resistance of the coils).

It was explained earlier that, in some aspects, it is desirable to move object 502 as fast as the system can allow without impacting accurate pattern transfers (e.g., in order to meet throughput goals). Faster actuation can be achieved by applying forces on support structure 604 exceeding 4 g, 100 g, or more. The magnetic saturation limit of the material of core 610 can impede efforts to increase the force by increasing the current I through the coils. However, based on equations 1 and 2, the force F can also be increased by decreasing distance d. Based on the features described above, two conflicting interests can be identified regarding the actuation of object 502 (FIG. 5). On one hand, it is desirable to engineer the full range of distance d such that the motion budget is accommodated (e.g., support structure 604 can be configured to move within a range of 1 mm) while allowing actuation target 608 and poles 618 to get as close as possible without touching. On the other hand, decreasing the distance d can increase the probability that actuation target 608 and core 610 can collide (due to tolerances in machining and/or construction).

The structures and methods disclosed herein allow for very low tolerance fabrication of the positional relationships of bumpers and the structures the bumpers are meant to protect. This allows closer placement of actuator target 608 to core 610 while mitigating risk of collision.

In some aspects, each of target-side bumper structures 628 can comprise a surface 634 (e.g., a contact surface). Surface 634 can define a plane 638 of target-side bumper structures 628. Similarly, each of core-side bumper structures 630 can comprise a surface 636 (e.g., a contact surface). Surface 636 can define a plane 640 of core-side bumper structures 630. In the event of a crash, surface 634 can make contact with surface 636. When the bumpers are engineered correctly, at the moment of contact, a non-zero collision avoidance gap is preserved (i.e., the distance d at its smallest is non-zero). That is, a target-side bumper can be configured to collide with a core-side bumper structure to establish a collision avoidance gap between the core and the target. And an uncertainty value of the collision avoidance gap can be less than approximately 20 microns, 50 microns, 70 microns, 100, microns, 120 microns, or the like. In alternative phrasing, when the distance between planes 638 and 640 is zero, the distance between planes 620 and 624 is greater than zero. And, though greater than zero, the collision avoidance gap can be made very small (e.g., uncertainty in the order of tens of nanometers) when manufactured according to one or more aspects of the present disclosure.

In some aspects, the manufacture of target-side structures can comprise affixing target-side bumper structures 628 to actuation target 608. The affixing can be achieved using any suitable method (e.g., adhesively bonded, bolted, nailed, clamped, or the like). Once affixed, the positional relationship between pole-facing side 622 (plane 624) and surface 634 is rendered fixed. When target-side bumper structure 628 and actuation target 608 are affixed to one another, precision shaping techniques (e.g., chemical mechanical polishing, ablation, precision coating, or the like) can be applied in order to precisely set the distance between planes 624 and 638. The precision shaping techniques can be applied on pole-facing side 622, surface 634, or both. The precision can be to a tolerance of, e.g., +/−5 microns. For example, planes 624 and 638 can be fabricated so as to be +130 microns apart with an uncertainty of +/−5 microns. The plus sign in +130 microns can indicate that surface 634 is disposed higher than pole-facing side 622.

In some aspects, a similar fabrication process can be performed on the core. The manufacture of core-side structures can comprise affixing core-side bumper structures 630 to core 610. The affixing can be achieved using any suitable method (e.g., adhesively bonded, bolted, nailed, clamped, or the like). Once affixed, the positional relationship between poles 618 (plane 620) and surface 640 is rendered fixed. When target-side bumper structure 628 and actuation target 608 are affixed to one another, precision shaping techniques (e.g., chemical mechanical polishing, ablation, precision coating, or the like) can be applied in order to precisely set the distance between planes 620 and 640. The precision shaping techniques can be applied on the surface of poles 618, surface 636, or both. The precision can be to a tolerance of, e.g., +/−5 microns. For example, planes 620 and 640 can be fabricated so as to be −100 microns apart with an uncertainty of +/−5 microns. The minus sign in −100 microns can indicate that surface 636 is disposed lower than the surface of poles 618.

In this non-limiting example, when surfaces 634 and 636 make contact, the collision avoidance gap (e.g., the smallest value of distance d allowed by the bumpers) is +130−100±5±5 microns=30±10 microns. Even in the worst case scenario (−10 microns of the uncertainty range), the collision avoidance gap is guaranteed to be 20 microns. That is, the collision avoidance gap can be fabricated to be in a set of tight ranges, for example, approximately 40 microns or less, 35 microns or less, 30 microns or less, 25 microns or less, 20 microns or less, or the like. It is noted that conventional methods of manufacturing bumpers are unable to reach such low tolerances. Conventional methods rely on precision machining of the bumpers, connectors, actuation target, and core before assembling the components. In conventional assembly, the parameters that can contribute to uncertainties can include the actuation target dimensions, target-side bumper dimensions, positioning of target-side bumper on its support structure, core dimensions, core-side bumper dimensions, positioning of core-side bumper on its support structure, epoxy bond thicknesses, and the like. The resulting total uncertainty according to conventional assembly can be ±200 microns or greater. This means that the collision avoidance gap should be engineered to be larger than 200 microns. And this difference of values of the collision avoidance gap (200 microns in conventional assembly vs. 20 microns according to aspects of the present disclosure) can result in an enhancement of the force F by 100-fold (F∝1/d², according to Eqs. 1 and 2).

In some aspects, the enhancement of the force F by manipulating the distance d can also be useful for reducing the amount of power consumed by coils 512 (FIG. 5). For a given amount of force, reducing the collision avoidance gap can result in considerably less power consumption when applying a force on support structure 604 (F∝I/d², according to Eqs. 1 and 2, and P=I²R).

In some aspects, stage 600 can comprise a kinetic energy dissipation system 642. Kinetic energy dissipation system 642 can comprise one or more collapsible structures (e.g., springs, flexures, hydraulics, or the like). Kinetic energy dissipation system 642 can be coupled to core 610. Kinetic energy dissipation system 642 can be coupled to core support structure 632. When surfaces 634 and 636 make contact during a collision, kinetic energy dissipation system 642 can collapse or otherwise give, allowing core 610 to be pushed out of position. The energy of the collision can be dissipated by kinetic energy dissipation system 642. Since kinetic energy dissipation system 642 can bias core 610 toward the left in the figure (toward actuation target 608), a stop structure (not shown) can be implemented in order to limit the motion of core 610 beyond a given position.

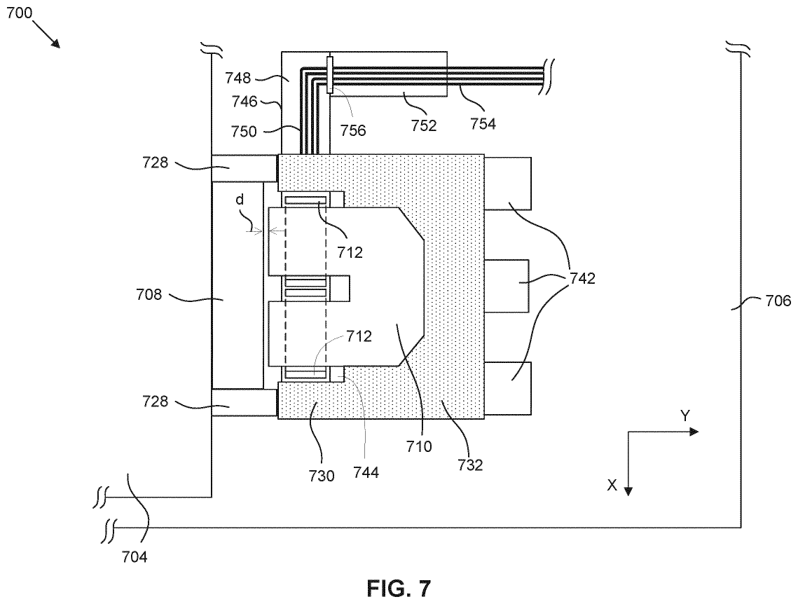

In some aspects, core support structure 632 can comprise slots 644. Slots 644 can provide clearance for coils that wrap around core 610. Coils 512 (FIG. 5) can be tightly wound around one or more portions of core 610 such that the coils are effectively affixed to core 610 by friction (other suitable affixing techniques can be used, such as, e.g., adhesive). The coils can also include cooling to offset the heat generated by electrical currents (e.g., fluid coolant circulation via ducting). However, if a need to service and/or replace core 610 arises, the wiring and ducting can impose some inconvenient constraints to the servicing technician. With the coils being affixed to the core, replacing the core can also include a complication of replacing the wiring/ducting along with the core. Therefore, in some aspects, the coils can be a detachable assembly as shown in FIG. 7.

FIG. 7 shows a portion of a stage 700, according to some aspects. In some aspects, stage 700 can comprise a different view of stages 500 and 600 (FIGS. 5 and 6) for illustrating additional details. For clarity purposes, new elements may be shown while some may be hidden or unlabeled. Therefore, unless otherwise noted, descriptions of elements of FIGS. 5 and 6 can also apply to FIG. 7. Elements appearing in FIG. 7 that correspond to elements in FIGS. 5 and 6 can have like reference numbers (e.g., reference numbers sharing the two right-most numeric digits). Examples of such elements in FIG. 7 can include, for example, support structures 704 and 706, actuator target 708, and core 710, coils 712, target-side bumper structures 728, core-side bumper structures 730, core support structure 732, kinetic energy dissipation system 742, and slots 744.

In some aspects, the force-generating elements of stage 700 can be portions of an electromagnetic apparatus (e.g., core 710, coils 712, etc.). The electromagnetic apparatus can comprise a detachable wire coil assembly 746. Detachable wire coil assembly 746 can comprise a housing 748, conduits 750, and coils 712. Coils 712 can wrap around core 710 (dashed lines show portions of the coils that go over/under core 710). Conduits 750 can be one or more conduits for providing electrical power to the coils, circulating cooling fluid, or the like. Detachable wire coil assembly 746 can be a modular part that can be affixed to, and detached from, support structure 706 via connector structure 752. To allow for modularity, though coils 712 wrap around core 710, coils 712 can have a detached arrangement (e.g., not affixed) with respect to core 710 (e.g., coils 712 and core 710 are allowed to move relative to one another). Coils 712 can fit in slots 744.

In some aspects, connector structure 752 can be rigid relative to support structure 706 (e.g., invariant in the reference frame of support structure 706). Support structure 706 can comprise conduits 754 that correspond to conduits 750 of detachable wire coil assembly 746. Conduits 754 and 750 can be mated via a mating-interface 756. Detachable wire coil assembly 746 can comprise one side of the mating-interface. Connector structure 752 of support structure 706 can comprise the other side of the mating interface. Mating-interface 756 can comprise an o-ring groove and an o-ring inserted in the o-ring groove. The o-ring can seal mating-interface 756 to prevent leaks. Support structure 706 can be fluidically coupled to a cooling system via conduits 754. Conduits 750 can be fluidically coupled to the cooling system via support structure 706. The modularity of detachable wire coil assembly 746 allows a technician to conveniently service and/or replace detachable wire coil assembly 746 without having to remove core 710 (the opposite also works, servicing and/or replacing core 610 without removing detachable wire coil assembly 746). In contrast, electromagnets provided as a rigid assembly of coils, core, and conduits can be cumbersome to service.

In some aspects, core 710 can be allowed to move independently of coils 712 (e.g., during a collision). FIG. 7 shows a snapshot of stage 700 in a collision state (target-side bumper structures 728 in contact with core-side bumper structures 730). As core 710 is pushed back, coils 712 can be at rest in the frame of support stage 706 while crash energy is dissipated by kinetic energy dissipation system 742. That is, kinetic energy dissipation system 742 can allow for a movement budget of core 710 relative to support structure 706 in order to dissipate collision energy. As shown in FIG. 7, the minimum distance d (e.g., collision avoidance gap) can be preserved and is invariant with respect to a replacement of detachable wire coil assembly 746. In contrast, electromagnets provided as a rigid assembly of coils, core, and conduits can introduce additional calibration of the collision avoidance gap due to a removal of the core along with the coils, which can undesirably prolong the performing of the installation.

In some aspects, though one core is shown in FIGS. 6 and 7, it is to be appreciated that the setup in FIGS. 6 and 7 can be iterated for multiple cores.

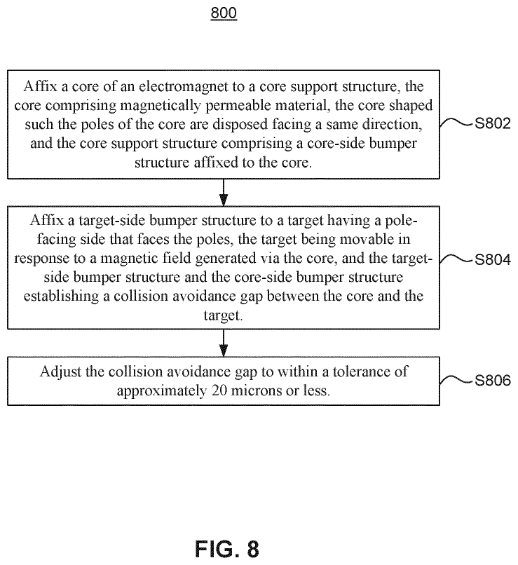

FIG. 8 shows a method 800 for fabricating the collision avoidance gap discussed above with a small tolerance, according to some aspects. In some aspects, at step S802, a core of an electromagnet apparatus can be affixed to a core support structure (e.g., core 710 affixed to core support structure 732 (FIG. 6)). The core can comprise magnetically permeable material. The core can be shaped such that the poles of the core are disposed facing a same direction. The core support structure can comprise a core-side bumper structure affixed to the core. At step S804, a target-side bumper structure can be affixed to a target. The target can have a pole-facing side that faces the poles of the core. The target can be movable in response to a magnetic field generated via the core. The target-side bumper structure can be configured to collide with the core-side bumper structure to establish a collision avoidance gap between the core and the target. At step S806, the collision avoidance gap can be adjusted to within a tolerance of approximately 20 microns or less, 50 microns or less, 70 microns or less, 100 microns or less, 120 microns or less, or the like.

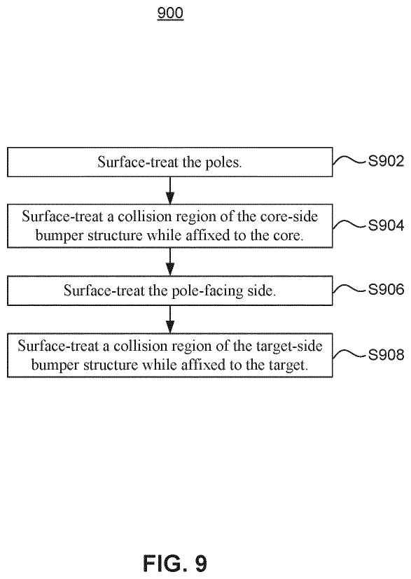

FIG. 9 shows a method 900 for fabricating the collision avoidance gap discussed above with a small tolerance, according to some aspects. In some aspects, method 900 can comprise operations for the adjusting step S806 in FIG. 8. For example, the adjusting in step S806 can further comprise surface-treating core-side structures and/or surface-treating target-side structures. The following steps can be performed on the core-side structures. At step S902, the poles can be surface-treated using a precision-shaping technique (e.g., chemical mechanical polishing, ablation, precision coating, or the like). At step S904, a collision region of the core-side bumper structure can be surface-treated using a precision-shaping technique while the core-side bumper structure is affixed to the core. In this manner, a relative distance between a plane of the poles and a plane of the core-side bumper structure can be adjusted to a high degree of accuracy. The following steps can be performed on the target-side structures. At step S906, the pole-facing side of the target can be surface-treated using a precision-shaping technique. At step S908, a collision region of the target-side bumper structure can be surface-treated using a precision-shaping technique while the target-side bumper structure is affixed to the target. In this manner, a relative distance between a plane of the target and a plane of the target-side bumper structure can be adjusted to a high degree of accuracy.

The method steps of FIGS. 8 and 9 can be performed in any conceivable order and it is not required that all steps be performed. Moreover, the method steps of FIGS. 8 and 9 described above merely reflect an example of method steps and are not limiting. That is, further method steps and functions are envisaged based aspects described in reference to FIGS. 1-7. For example, a kinetic energy dissipation system can be affixed to a support structure. A detachable (modular) wire coil assembly comprising a wire coil can be installed. The wire coiled can be disposed to wrap around a portion of the core. The detachable wire coil assembly can be affixed to the support structure while keeping the detachable wire coil assembly disjoined from the core to allow the core to move relative to the support structure during a collision event (e.g., the detachable wire coil assembly remains substantially at rest with respect to the support structure during the collision event). The detachable wire coil assembly can be uninstalled without altering the collision avoidance gap by decoupling the detachable wire coil assembly from the support structure and sliding the detachable wire coil assembly off of the core.

The terms “radiation,” “beam,” “light,” “illumination,” or the like can be used herein to refer to one or more types of electromagnetic radiation, for example, ultraviolet (UV) radiation (for example, having a wavelength, of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Various embodiments of the present systems and methods are disclosed in the subsequent list of numbered clauses:
1. A stage for supporting and moving an object, the stage comprising:
   an electromagnet comprising:
      a core disposed on a first support structure and comprising magnetically permeable material, wherein the core is shaped such that poles of the core are disposed facing a same direction;
      a wire coil configured to generate a magnetic field in the core; and
      a core-side bumper structure affixed to the core;
   a second support structure configured to support and move the object relative to the first support structure;
   a target disposed on the second support structure and configured to actuate the second support structure in response to the generating of the magnetic field; and
   a target-side bumper structure affixed to the target and configured to collide with the core-side bumper structure to establish a collision avoidance gap between the core and the target.
2. The stage of clause 1, wherein an uncertainty value of the collision avoidance gap is less than approximately 20 microns, wherein the uncertainty is based on:
   the core-side bumper structure being disposed directly on the core; and/or
   the target-side bumper structure being disposed directly on the target.
3. The stage of clause 1, wherein the core-side bumper structure comprises a polished collision surface and/or the target-side bumper comprises a polished collision surface.
4. The stage of clause 1, wherein the wire coil is affixed to the first support structure, shaped to wrap around at least a portion of the core, and disjoined from the core so as to allow the core to move relative to the wire coil.
5. The stage of clause 1, further comprising a kinetic energy dissipation system affixed to the first support structure and the core, wherein the kinetic energy dissipation system is configured to compress upon collision of the core-side bumper structure and the target-side bumper structure and to allow the core to move relative to the first support structure to dissipate energy of the collision.
6. The stage of clause 5, wherein the wire coil is disjoined from the core so as to allow the core to move relative to the wire coil during the collision.
7. The stage of clause 1, wherein:
   the core comprises a core support structure affixed to the core and comprising the core-side bumper structure; and
   the core-side bumper structure and the core support structure are monolithic.
8. The stage of clause 1, wherein the wire coil is part of a modular wire coil assembly comprising a conduit configured to guide a cooling fluid to regulate a temperature of the wire coil.
9. The stage of clause 8, wherein:
   a mating-interface of the modular wire coil assembly comprises an an o-ring groove configured to receive an o-ring to seal a connection between the conduit and a cooling system configured to fluidically couple with the conduit;
   the mating-interface is configured to mate with the first support structure; and
   the first support structure is fluidically coupled to the cooling system.
10. The stage of clause 8, wherein the collision avoidance gap is invariant with respect to a replacement of the modular wire coil assembly.
11. An electromagnet apparatus comprising:
   a core comprising magnetically permeable material, wherein the core is shaped such that poles of the core are disposed facing a same direction; and
   a detachable wire coil assembly comprising:
      a wire coil configured to generate a magnetic field in the core; and
      a housing comprising a conduit configured to guide a cooling fluid to regulate a temperature of the wire coil.
12. The electromagnet apparatus of clause 11, wherein:
   the detachable wire coil assembly further comprises a mating-interface disposed at a surface of the housing; and
   the mating-interface comprises an o-ring groove configured to receive an o-ring to seal a connection between the conduit and a system configured to fluidically couple with the conduit.
13. The electromagnet apparatus of clause 11, wherein:
   the core is disposed on a support structure; and
   the electromagnet is configured to actuate a target disposed on a movable support device in response to the generating of the magnetic field.
14. The electromagnet apparatus of clause 13, wherein:
   the mating-interface is configured to mate with the support structure; and
   the support structure is fluidically coupled to the cooling system.
15. The electromagnet apparatus of clause 13, wherein:
   a core-side bumper structure is affixed to the core;
   a target-side bumper structure is affixed to the movable support device;
   the core-side bumper structure and the target-side bumper structure are configured to collide and to establish a collision avoidance gap between the core and the target; and
   an uncertainty value of the collision avoidance gap is less than approximately 20 microns.
16. The electromagnet apparatus of clause 15, wherein the collision avoidance gap is invariant with respect to a replacement of the detachable wire coil assembly.
17. A method of fabricating an electromagnetic actuator having a collision safety mechanism, the method comprising:
   affixing a core of an electromagnet to a core support structure, wherein the core comprises magnetically permeable material, the core is shaped such poles of the core are disposed facing a same direction, and the core support structure comprises a core-side bumper structure affixed to the core;
   affixing a target-side bumper structure to a target having a pole-facing side that faces the poles, wherein the target is movable in response to a magnetic field generated via the core, and the target-side bumper structure is configured to collide with the core-side bumper structure to establish a collision avoidance gap between the core and the target; and
   adjusting the collision avoidance gap to within a tolerance of approximately 20 microns or less, the adjusting comprising:
      surface-treating core-side structures, comprising:
         surface-treating the poles; and
         surface-treating a collision region of the core-side bumper structure while affixed to the core; and/or
      surface-treating target-side structures, comprising:
         surface-treating the pole-facing side; and
         surface-treating a collision region of the target-side bumper structure while affixed to the target.
18. The method of clause 17, further comprising:
   affixing a kinetic energy dissipation system to a support structure and the core, wherein the kinetic energy dissipation system allows a movement budget of the core relative to the support structure to dissipate collision energy;
   installing a modular wire coil assembly comprising a wire coil configured to generate the magnetic field, wherein the installing comprises:
      disposing the wire coil to wrap around a portion of the core; and
      affixing the modular wire coil assembly to the support structure, the modular wire coil assembly being a disjoined structure with respect to the core to allow the core to move relative to the support structure during a collision event.
19. The method of clause 18, wherein:
   the modular wire coil assembly comprises:
      a conduit configured to guide a cooling fluid to regulate a temperature of the wire coil; and
      a mating-interface comprising an o-ring groove; and
   the installing further comprises:
      disposing an o-ring in the o-ring groove; and
      mating the mating-interface to the support structure to form a seal of the conduit using the o-ring.
20. The method of clause 18, further comprising uninstalling the modular wire coil assembly without altering the collision avoidance gap, the uninstalling comprising:
   decoupling the wire modular coil assembly from the support structure; and
   sliding the disjoined structure off of the core.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1.-15. (canceled)

16. A stage for supporting and moving an object, the stage comprising:
an electromagnet comprising:
a core disposed on a first support structure and comprising magnetically permeable material, wherein the core is shaped such that poles of the core are disposed facing a same direction;
a wire coil configured to generate a magnetic field in the core; and
a core-side bumper structure affixed to the core;
a second support structure configured to support and move the object relative to the first support structure;
a target disposed on the second support structure and configured to actuate the second support structure in response to the generating of the magnetic field; and
a target-side bumper structure affixed to the target and configured to collide with the core-side bumper structure to establish a collision avoidance gap between the core and the target.

17. The stage of claim 16, wherein an uncertainty value of the collision avoidance gap is less than approximately 20 microns, wherein the uncertainty is based on:
the core-side bumper structure being disposed directly on the core; and/or
the target-side bumper structure being disposed directly on the target.

18. The stage of claim 16, wherein the core-side bumper structure comprises a polished collision surface and/or the target-side bumper comprises a polished collision surface.

19. The stage of claim 16, wherein the wire coil is affixed to the first support structure, shaped to wrap around at least a portion of the core, and disjoined from the core so as to allow the core to move relative to the wire coil.

20. The stage of claim 16, further comprising a kinetic energy dissipation system affixed to the first support structure and the core, wherein the kinetic energy dissipation system is configured to compress upon collision of the core-side bumper structure and the target-side bumper structure and to allow the core to move relative to the first support structure to dissipate energy of the collision, wherein the wire coil is disjoined from the core so as to allow the core to move relative to the wire coil during the collision.

21. The stage of claim 16, wherein:
the core comprises a core support structure affixed to the core and comprising the core-side bumper structure; and
the core-side bumper structure and the core support structure are monolithic.

22. The stage of claim 16, wherein the wire coil is part of a modular wire coil assembly comprising a conduit configured to guide a cooling fluid to regulate a temperature of the wire coil, wherein:
a mating-interface of the modular wire coil assembly comprises an an o-ring groove configured to receive an o-ring to seal a connection between the conduit and a cooling system configured to fluidically couple with the conduit;
the mating-interface is configured to mate with the first support structure;
the first support structure is fluidically coupled to the cooling system; and the collision avoidance gap is invariant with respect to a replacement of the modular wire coil assembly.

23. An electromagnet apparatus comprising:
a core comprising magnetically permeable material, wherein the core is shaped such that poles of the core are disposed facing a same direction; and
a detachable wire coil assembly comprising:
a wire coil configured to generate a magnetic field in the core; and
a housing comprising a conduit configured to guide a cooling fluid to regulate a temperature of the wire coil.

24. The electromagnet apparatus of claim 23, wherein:
the detachable wire coil assembly further comprises a mating-interface disposed at a surface of the housing; and
the mating-interface comprises an o-ring groove configured to receive an o-ring to seal a connection between the conduit and a system configured to fluidically couple with the conduit.

25. The electromagnet apparatus of claim 23, wherein:
the core is disposed on a support structure; and
the electromagnet is configured to actuate a target disposed on a movable support device in response to the generating of the magnetic field, wherein:
the mating-interface is configured to mate with the support structure; and
the support structure is fluidically coupled to the cooling system.

26. The electromagnet apparatus of claim 25, wherein:
a core-side bumper structure is affixed to the core;
a target-side bumper structure is affixed to the movable support device;
the core-side bumper structure and the target-side bumper structure are configured to collide and to establish a collision avoidance gap between the core and the target; and
an uncertainty value of the collision avoidance gap is less than approximately 20 microns, wherein the collision avoidance gap is invariant with respect to a replacement of the detachable wire coil assembly.

27. A method of fabricating an electromagnetic actuator having a collision safety mechanism, the method comprising:
affixing a core of an electromagnet to a core support structure, wherein the core comprises magnetically permeable material, the core is shaped such poles of the core are disposed facing a same direction, and the core support structure comprises a core-side bumper structure affixed to the core;
affixing a target-side bumper structure to a target having a pole-facing side that faces the poles, wherein the target is movable in response to a magnetic field generated via the core, and the target-side bumper structure is configured to collide with the core-side bumper structure to establish a collision avoidance gap between the core and the target; and
adjusting the collision avoidance gap to within a tolerance of approximately 20 microns or less, the adjusting comprising:
surface-treating core-side structures, comprising:
surface-treating the poles; and
surface-treating a collision region of the core-side bumper structure while affixed to the core; and/or
surface-treating target-side structures, comprising:
surface-treating the pole-facing side; and
surface-treating a collision region of the target-side bumper structure while affixed to the target.

28. The method of claim 27, further comprising:
affixing a kinetic energy dissipation system to a support structure and the core, wherein the kinetic energy dissipation system allows a movement budget of the core relative to the support structure to dissipate collision energy;
installing a modular wire coil assembly comprising a wire coil configured to generate the magnetic field, wherein the installing comprises:
disposing the wire coil to wrap around a portion of the core; and
affixing the modular wire coil assembly to the support structure, the modular wire coil assembly being a disjoined structure with respect to the core to allow the core to move relative to the support structure during a collision event.

29. The method of claim 28, wherein:
the modular wire coil assembly comprises:
a conduit configured to guide a cooling fluid to regulate a temperature of the wire coil; and
a mating-interface comprising an o-ring groove; and
the installing further comprises:
disposing an o-ring in the o-ring groove; and
mating the mating-interface to the support structure to form a seal of the conduit using the o-ring.

30. The method of claim 28, further comprising uninstalling the modular wire coil assembly without altering the collision avoidance gap, the uninstalling comprising:
decoupling the wire modular coil assembly from the support structure; and
sliding the disjoined structure off of the core.
